(19) United States
(12) Patent Application Publication
(10) Pub. No.: US 2009/0267042 A1
(43) Pub. Date: Oct. 29, 2009

(54) Integrated Circuit and Method of Manufacturing an Integrated Circuit

(76) Inventors: Thomas D. Happ, Dresden (DE); Igor Kasko, Dresden (DE); Andreas Walter, Dresden (DE)

Correspondence Address: SLATER & MATSIL, L.L.P., 17950 PRESTON ROAD, SUITE 1000, DALLAS, TX, 75252, US

(21) Appl. No.: 12/109,231

(22) Filed: Apr. 24, 2008

(51) Int. Cl. H01L 47/00; H01L 21/00

(52) U.S. Cl. 257/2; 438/102; 438/128; 257/E21.001; 257/E47.001

(57) ABSTRACT

According to one embodiment of the present invention, an integrated circuit including a plurality of resistance changing memory cells is provided. Each memory cell includes: a semiconductor substrate; a select device arranged within the semiconductor substrate; and a memory element being arranged above the semiconductor substrate. The select device is a diode comprising a first semiconductor area of a first conductive type and a second semiconductor area of a second conductive type which are arranged adjacent to each other such that a lateral pn-junction is formed. The first semiconductor area is connected to a word line arranged on or above the semiconductor substrate. The second semiconductor area is connected to the memory element via a conductive connection element.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic perspective view of an integrated circuit including magneto-resistive memory cells;

FIG. 2 shows a schematic drawing of an integrated circuit usable in conjunction with the integrated circuit shown in FIG. 1;

FIG. 3 shows a schematic drawing of an integrated circuit including phase change memory cells;

FIG. 4 shows a schematic cross-sectional view of a phase change memory element;

FIG. 5 shows a schematic drawing of an integrated circuit including resistance changing memory cells;

FIG. 6A shows a schematic cross-sectional view of a carbon memory element set to a first switching state;

FIG. 6B shows a schematic cross-sectional view of a carbon memory element set to a second switching state;

FIG. 7 shows a schematic drawing of a resistance changing memory cell;

FIG. 8 shows a schematic cross-sectional view of an integrated circuit according to one embodiment of the present invention;

FIG. 9 shows a schematic top view of an integrated circuit according to one embodiment of the present invention;

FIG. 10 shows a schematic cross-sectional view of an integrated circuit according to one embodiment of the present invention;

FIG. 11 shows a schematic top view of an integrated circuit according to one embodiment of the present invention;

FIG. 12 shows a schematic cross-sectional view of an integrated circuit according to one embodiment of the present invention;

FIG. 13 shows a schematic top view of an integrated circuit according to one embodiment of the present invention;

FIG. 14 shows a schematic cross-sectional view of an integrated circuit according to one embodiment of the present invention;

FIG. 15 shows a schematic top view of an integrated circuit according to one embodiment of the present invention;

FIG. 16 shows a schematic cross-sectional view of an integrated circuit according to one embodiment of the present invention;

FIG. 17 shows a schematic cross-sectional view of an integrated circuit according to one embodiment of the present invention;

FIG. 18 shows a schematic top view of an integrated circuit according to one embodiment of the present invention;

FIG. 19 shows a schematic top view of an integrated circuit according to one embodiment of the present invention;

FIG. 20 shows a schematic top view of an integrated circuit according to one embodiment of the present invention;

FIG. 21 shows a flow chart of a method of manufacturing an integrated circuit according to one embodiment of the present invention;

FIG. 22A shows a schematic perspective view of a memory module according to one embodiment of the present invention; and

FIG. 22B shows a schematic perspective view of a memory module according to one embodiment of the present invention.

### DETAILED DESCRIPTION OF ILLUSTRATIVE EMBODIMENTS

Since the embodiments of the present invention can be applied to magneto-resistive memory devices which include resistance changing memory cells (magneto-resistive memory cells), a brief discussion of magneto-resistive memory devices will be given. In magneto-resistive memory cells, material magnetization and hence electron spin rather than charge is used to store “1” or “0”. A collection of magneto-resistive memory cells form a magnetic random-access memory (MRAM), which includes conductive lines positioned perpendicular to one another in different metal layers, the conductive lines sandwiching a magnetic stack. The place where the conductive lines intersect is called a cross-point. A current flowing through one of the conductive lines generates a magnetic field around the conductive line and orients the magnetic polarity into a certain direction along the wire or conductive line. A current flowing through the other conductive line induces the magnetic field and can also partially turn the magnetic polarity. Digital information, represented as a “0” or “1” is stored in the alignment of magnetic moments. The resistance of the magnetic component depends on the moment's alignment. The stored state is read from the element by detecting the component's resistive state. A memory cell may be constructed by placing the conductive lines and cross-points in a matrix structure or array having rows and columns.

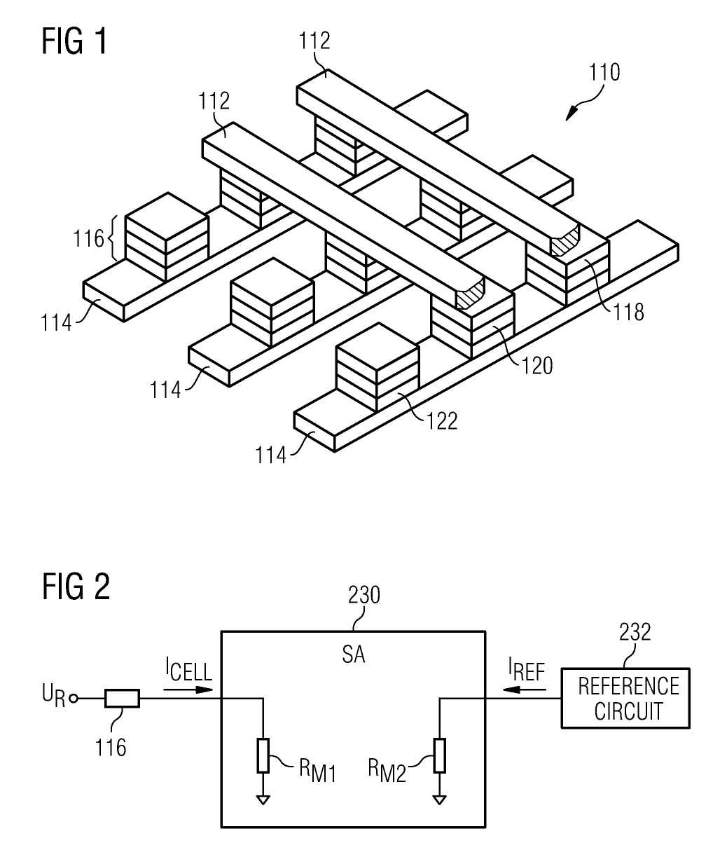

FIG. 1 illustrates a perspective view of a MRAM device 110 having bit lines 112 located orthogonal to word lines 114 in adjacent metallization layers. Magnetic stacks 116 are positioned between the bit lines 112 and word lines 114 adjacent and electrically coupled to bit lines 112 and word lines 1 14. Magnetic stacks 116 preferably include multiple layers, including a soft layer 118, a tunnel layer 120, and a hard layer 122, for example. Soft layer 118 and hard layer 122 preferably include a plurality of magnetic metal layers, for example, eight to twelve layers of materials such as PtMn, CoFe, Ru, and NiFe, as examples. A logic state is storable in the soft layer 118 of the magnetic stacks 116 located at the junction of the bit lines 112 and word lines 114 by running a current in the appropriate direction within the bit lines 112 and word lines 114, which changes the resistance of the magnetic stacks 1 16.

In order to read the logic state stored in a soft layer 118 of a selected magnetic stack 116, a schematic such as the one shown in FIG. 2, including a sense amplifier (SA) 230, may be used. A reference voltage U_{R} is applied to one end of the selected magnetic stack 1 16. The other end of the selected magentic stack 116 is coupled to a measurement resistor Rₘ₁. The other end of the measurement resistor Rₘ₁ is coupled to ground. The current running through the selected magnetic stack is equal to current I_{cell}. A reference circuit 232 supplies a reference current I_{ref} that is run into measurement resistor Rₘ₂. The other end of the measurement resistor Rₘ₂ is coupled to ground, as shown.

Since the embodiments of the present invention can be applied to phase change memory devices that include resistance changing memory cells (phase change memory cells), a brief discussion of phase change memory devices will be given.

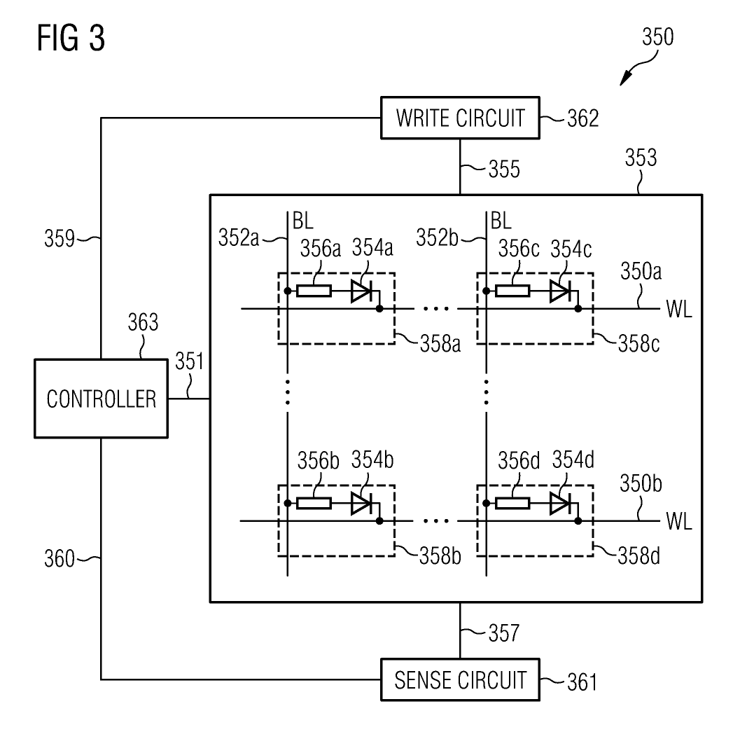

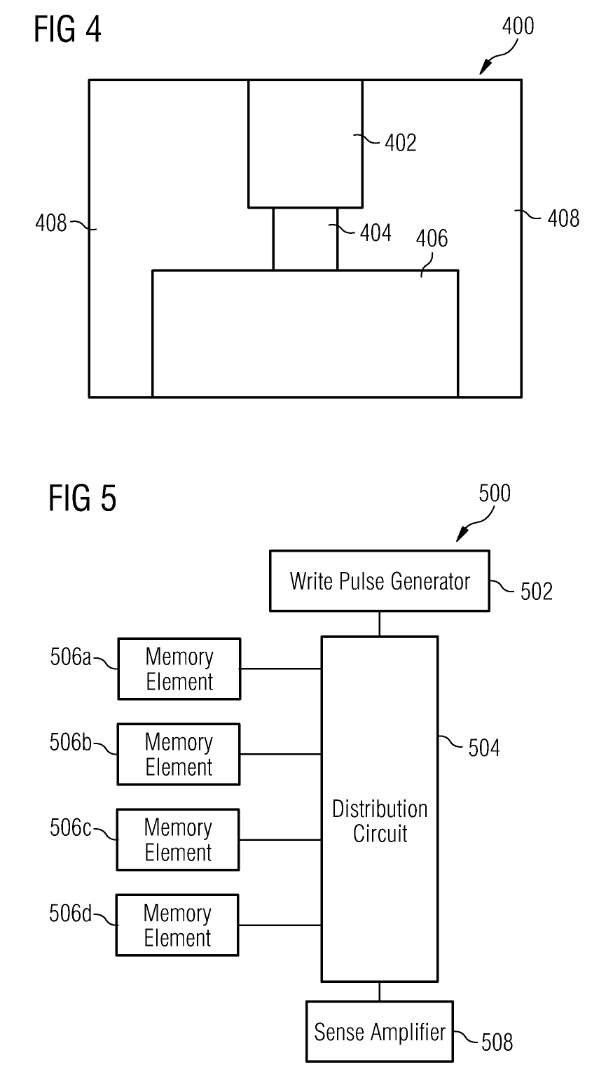

FIG. 3 shows a PCRAM-device 350 having an array of memory cells 353, a writing circuit 362, a sensing circuit 361, a controller 363, and bit lines 352a, 352b being arranged perpendicular to the word lines 350a, 350b. PCRAM elements (phase change elements) 356a-356d are arranged between the bit lines 352a, 352b and the word lines 350a, 350b and are electrically coupled with the bit lines 352a, 352b and the word lines 350a, 350b. Between the PCRAM elements 356a-356d and the word lines 350a, 350b, select devices (here: diodes which may be replaced by field effect transistors or by bipolar transistors) 354a-354d are arranged, thus forming PCRAM memory cells 358a-358d. The controller 363 controls the sensing circuit 361 and the writing circuit 362 connected to the controller 363 via lines 359, 360. The writing circuit 362 sets the memory states of the memory cells 358a-358d via lines 355, and the reading circuit reads the memory states of the memory cells 358a-358d via lines 357. More details about PCRAM-devices will be given in conjunction with FIGS. 4 and 5.

According to one embodiment of the invention, the resistance changing memory elements are phase change memory elements that include a phase change material. The phase change material can be switched between at least two different crystallization states (i.e., the phase change material may adopt at least two different degrees of crystallization), wherein each crystallization state may be used to represent a memory state. When the number of possible crystallization states is two, the crystallization state having a high degree of crystallization is also referred to as “crystalline state”, whereas the crystallization state having a low degree of crystallization is also referred to as “amorphous state”. Different crystallization states can be distinguished from each other by their differing electrical properties and, in particular, by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase change material can adopt two crystallization states (an “amorphous state” and a “crystalline state”), however it will be understood that additional intermediate states may also be used.

Phase change memory elements may change from the amorphous state to the crystalline state (and vice versa) due to temperature changes of the phase change material. These temperature changes may be caused using different approaches. For example, a current may be driven through the phase change material (or a voltage may be applied across the phase change material). Alternatively, a current or a voltage may be fed to a resistive heater located adjacent to the phase change material. To determine the memory state of a resistance changing memory element, a sensing current may be routed through the phase change material (or a sensing voltage may be applied across the phase change material), thereby sensing its resistivity which represents the memory state of the memory element.

FIG. 4 illustrates a cross-sectional view of an exemplary phase change memory element 400 (active-in-via type). The phase change memory element 400 includes a first electrode 402, a phase change material 404, a second electrode 406, and an insulating material 408. The phase change material 404 is laterally enclosed by the insulating material 408. To use the phase change memory element, a selection device (not shown), such as a transistor, a diode, or another active device, may be coupled to the first electrode 402 or to the second electrode 406 to control the application of a current or a voltage to the phase change material 404 via the first electrode 402 and/or the second electrode 406. To set the phase change material 404 to the crystalline state, a current pulse and/or voltage pulse may be applied to the phase change material 404, wherein the pulse parameters are chosen such that the phase change material 404 is heated above its crystallization temperature, generally keeping the temperature below the melting temperature of the phase change material 404. To set the phase change material 404 to the amorphous state, a current pulse and/or voltage pulse may be applied to the phase change material 404, wherein the pulse parameters are chosen such that the phase change material 404 is briefly heated above its melting temperature, and is quickly quench cooled below its crystallization temperature.

The phase change material 404 may include a variety of materials. According to one embodiment, the phase change material 404 may include or consist of a chalcogenide alloy that includes one or more elements from group VI of the periodic table. According to another embodiment, the phase change material 404 may include or consist of a chalcogenide compound material, such as GeSbTe, SbTe, GeTe or AgInSbTe. According to a further embodiment, the phase change material 404 may include or consist of chalcogen free material, such as GeSb, GaSb, InSb, or GeGaInSb. According to still another embodiment, the phase change material 404 may include or consist of any suitable material including one or more of the elements Ge, Sb, Te, Ga, Bi, Pb, Sn, Si, P, O, As, In, Se, and S.

According to one embodiment, at least one of the first electrode 402 and the second electrode 406 may include or consist of Ti, V, Cr, Zr, Nb, Mo, Hf, Ta, W, or mixtures or alloys thereof. According to another embodiment, at least one of the first electrode 402 and the second electrode 406 may include or consist of Ti, V, Cr, Zr, Nb, Mo, Hf, Ta, W and one or more elements selected from the group consisting of B, C, N, O, Al, Si, P, S, and/or mixtures and alloys thereof. Examples of such materials include TiN, TiCN, TiAlN, TiSiN, W—Al₂O₃ and Cr—Al₂O₃.

FIG. 5 illustrates a block diagram of a memory device 500 including a write pulse generator 502, a distribution circuit 504, phase change memory elements 506a, 506b, 506c, 506d (for example phase change memory elements 400 as shown in FIG. 2), and a sense amplifier 508. According to one embodiment, the write pulse generator 502 generates current pulses or voltage pulses that are supplied to the phase change memory elements 506a, 506b, 506c, 506d via the distribution circuit 504, thereby programming the memory states of the phase change memory elements 506a, 506b, 506c, 506d. According to one embodiment, the distribution circuit 504 includes a plurality of transistors that supply direct current pulses or direct voltage pulses to the phase change memory elements 506a, 506b, 506c, 506d or to heaters being disposed adjacent to the phase change memory elements 506a, 506b, 506c, 506d.

As already indicated, the phase change material of the phase change memory elements 506a, 506b, 506c, 506d may be changed from the amorphous state to the crystalline state (or vice versa) under the influence of a temperature change. More generally, the phase change material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 508 is capable of determining the memory state of one of the phase change memory elements 506a, 506b, 506c, or 506d in dependence on the resistance of the phase change material.

To achieve high memory densities, the phase change memory elements 506a, 506b, 506c, 506d may be capable of storing multiple bits of data, i.e., the phase change material may be programmed to more than two resistance values. For example, if a phase change memory element 506a, 506b, 506c, 506d is programmed to one of three possible resistance levels, 1.5 bits of data per memory element can be stored. If the phase change memory element is programmed to one of four possible resistance levels, two bits of data per memory element can be stored, and so on.

The embodiment shown in FIG. 5 may also be applied in a similar manner to other types of resistance changing memory elements like magento-resistive memory elements (e.g., MRAMs), organic memory elements (e.g., ORAMs), or transition metal oxide memory elements (TMOs).

Another type of resistance changing memory element may be formed using carbon as a resistance changing material. Generally, amorphous carbon that is rich iN sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistance changing memory cell.

In one embodiment, a carbon memory element may be formed in a manner similar to that described above with reference to phase change memory elements. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory element, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

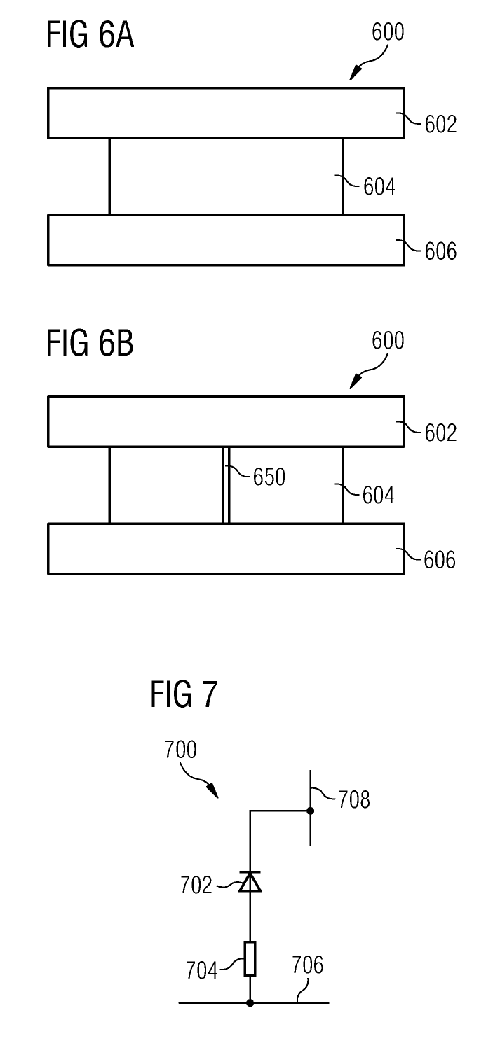

Another way in which resistivity changes in amorphous carbon can be used to store information is by electric field induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 6A and 6B.

FIG. 6A shows a carbon memory element 600 that includes a top contact 602, a carbon storage layer 604 including an insulating amorphous carbon material rich in sp³-hybridized carbon atoms, and a bottom contact 606. As shown in FIG. 6B, by forcing a current (or voltage) through the carbon storage layer 604, an sp² filament 650 can be formed in the sp³-rich carbon storage layer 604, changing the resistivity of the memory element. Application of a current (or voltage) pulse with higher energy (or, in some embodiments, reversed polarity) may destroy the sp² filament 650, increasing the resistance of the carbon storage layer 604. As discussed above, these changes in the resistance of the carbon storage layer 604 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory element. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistance changing memory elements, such as the phase change memory elements and carbon memory elements described above, may be used as part of a memory cell, along with a transistor, diode, or other active component for selecting the memory cell. FIG. 7 shows a schematic representation of such a memory cell that uses a resistance changing memory element. The memory cell 700 includes a select device (diode) 702 and a resistance changing memory element 704. The select device 702 is connected between the memory element 704 and a bit line 708. The resistance changing memory element 704 also is connected to a word line 706, which may be connected to ground, or to other circuitry, such as circuitry (not shown) for determining the resistance of the memory cell 700, for use in reading. Alternatively, in some configurations, circuitry (not shown) for determining the state of the memory cell 700 during reading may be connected to the bit line 708. In order to select a resistance changing memory element 704, the corresponding bit line 708 may, for example, be set to 3V, and the word line 706 may be set to ground. Non selected word lines may then be set to 3V, and non selected bit lines 708 may be grounded or left floating. It should be noted that, as used herein, the terms “connected” and “coupled” are intended to include both direct and indirect connection and coupling, respectively.

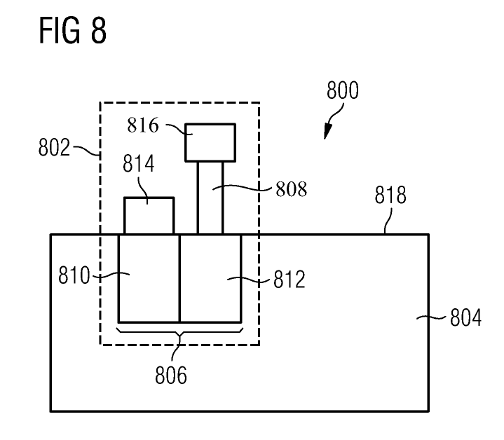

FIG. 8 shows an integrated circuit 800 according to one embodiment of the present invention. The integrated circuit 800 includes a plurality of resistance changing memory cells 802, each memory cell 802 including: a semiconductor substrate 804, a select device 806 arranged within the semiconductor substrate 804, and a memory element 816 being arranged above the semiconductor substrate 804. The select device 806 is a diode including a first semiconductor area 810 of a first conductive type and a second semiconductor area 812 of a second conductive type. The first semiconductor area 810 and the second semiconductor area 812 are arranged adjacent to each other. Here, a lateral pn-junction is formed. However, the present invention is not restricted thereto. Different junction shapes being more similar to a cup-shape than to a vertical plane may, for example, also be used. Further, in other embodiments, other junction shapes such as tilted 2D planes or even shallow horizontal cups are possible. The first semiconductor area 810 is connected to a word line 814 arranged on or above the semiconductor substrate 804. The second semiconductor area 812 is connected to the memory element 816 via a conductive connection element 808.

One effect of this embodiment is that the integration density of the integrated circuit 800 can be chosen very high. A further effect is that, as will become apparent in the following description, the manufacturing method of the integrated circuit 800 is rather easy.

According to one embodiment of the present invention, the first semiconductor area 810 and the second semiconductor area 812 extend from the top surface 818 of the semiconductor substrate 804 into the semiconductor substrate 804.

According to one embodiment of the present invention, the word line 814 directly contacts the top surface of the first semiconductor area 810.

According to one embodiment of the present invention, the semiconductor substrate 804 is covered by an isolation layer including a first trench and a second trench, wherein the word line 814 is formed by conductive material filled into the first trench, and wherein the conductive connection element 808 is formed by conductive material filled into the second trench. One effect of this embodiment is that the first trench and the second trench can be both used for forming the first semiconductor area 810 and the second semiconductor area 812 (for example, by a doping process that introduces doping material into the semiconductor substrate 804 via the trenches), while at the same time the first trench and the second trench can be used for forming the word line 814 and the conductive connection element 808 (by filling conductive material into the trenches).

According to one embodiment of the present invention, the word line 814 is formed of metal. One effect of this embodiment is that the resistance of such a word line is lower than a resistance of a word line of semiconducting material, for example, a buried semiconductor word line located below the select device 806 within the semiconductor substrate 804.

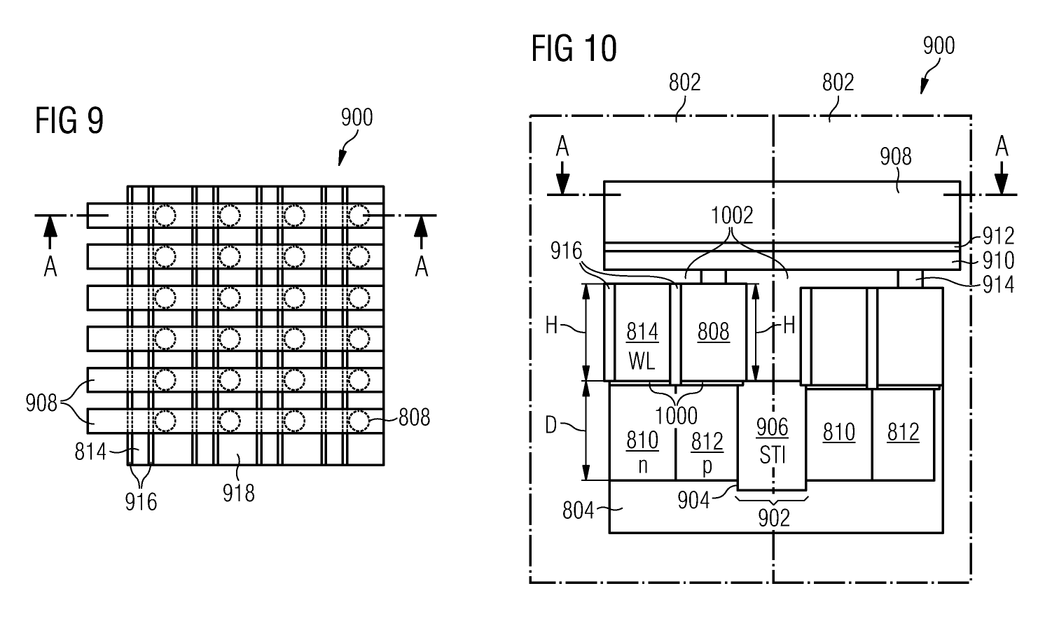

FIGS. 9 and 10 show an integrated circuit 900 according to one embodiment of the present invention. The integrated circuit 900 includes an isolation structure 902 which at least partly laterally isolates different memory cells 802 against each other. According to one embodiment of the present invention, the isolation structure 902 is a trench structure 904 filled with isolation material 906.

In this embodiment, the first semiconductor areas 810 and the second semiconductor areas 812 have the same depth D. Further, the word lines 814 and the conductive connection elements 808 have the same height H.

The integrated circuit 900 includes a plurality of bit lines 908 that are connected to resistance changing layers 910 via top electrodes 912. Bottom electrodes 914 connect the resistance changing layers 910 with the conductive connection elements 808. Here, it is assumed that one resistance changing layer 910 is shared by all memory cells connected to the same bit line 908. However, each resistance changing layer 910 may also be split up into a plurality of resistance changing memory elements which are laterally isolated against each other. In FIG. 10, it is assumed that the resistance changing layers 910 are phase change layers. The word lines 814 and the conductive connection elements 808 may be laterally isolated against each other by side wall spacers 916 of isolation material. Between different memory cells, isolation material 1002 is provided. Between the word lines 814 conductive connection elements 808 and the semiconductor substrate 804, a thin metal layer (silicide) 1000 may be respectively provided. FIG. 10 shows the integrated circuit 900 along line A as indicated in FIG. 9.

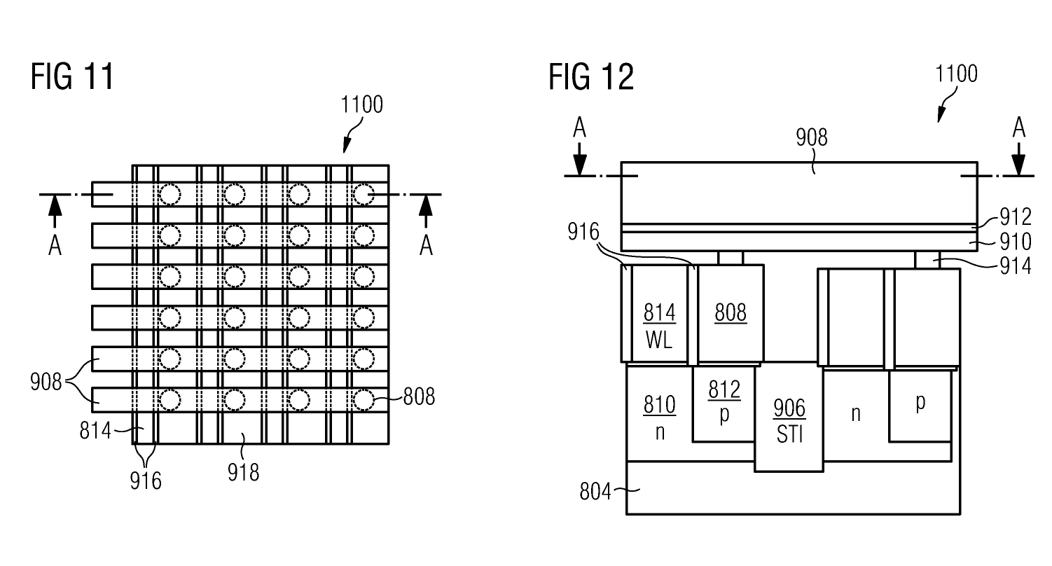

FIGS. 11 and 12 show an integrated circuit 1100, the architecture of which being very similar to that of the integrated circuit shown in FIGS. 9 and 10. However, the first semiconductor areas 810 and the second semiconductor areas 812 do not have the same depth, but have different depths. Further, the second semiconductor areas 812 are partly surrounded by the first semiconductor areas 810. This leads to a different junction shape, which is more similar to a cup-shape than to a vertical plane. In other embodiments, depending on the implant conditions and implant angles, other junction shapes such as tilted 2D planes or even shallow horizontal cups are possible. FIG. 12 shows the integrated circuit 1100 along line A as indicated in FIG. 11.

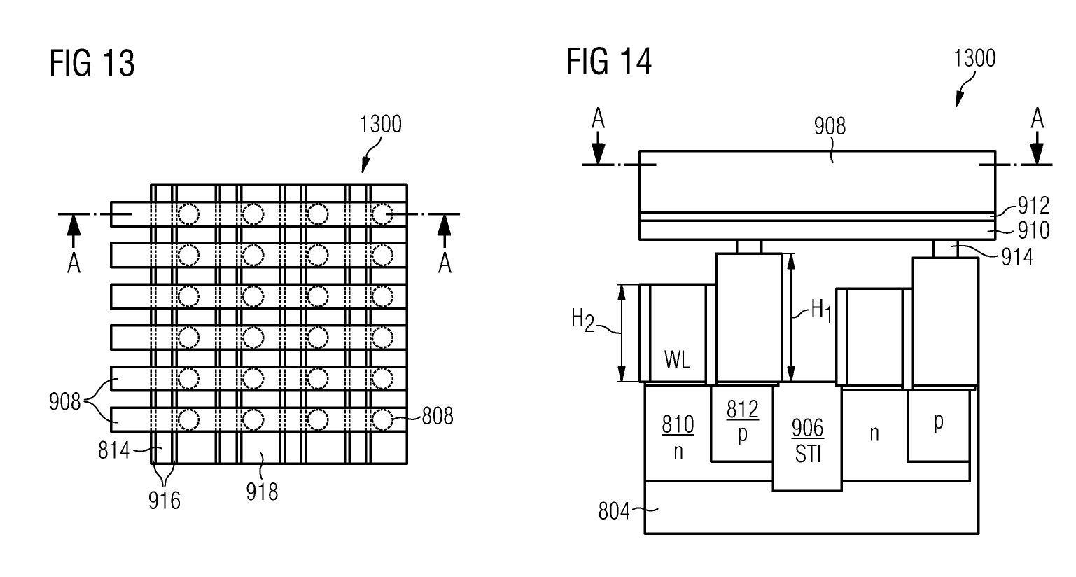

FIGS. 13 and 14 show an integrated circuit 1300, the architecture of which being similar to that of the integrated circuit 1100 shown in FIGS. 11 and 12. However, the height HI of word lines 814 is lower than the height H₂ of the conductive connection elements 808. One effect of this embodiment is that the danger of an undesired shortcut between the bottom electrodes 914 and the word lines 814 or between the resistance changing layers 910 and the word lines 814 can be reduced. FIG. 14 shows the integrated circuit 1300 along line A as indicated in FIG. 13.

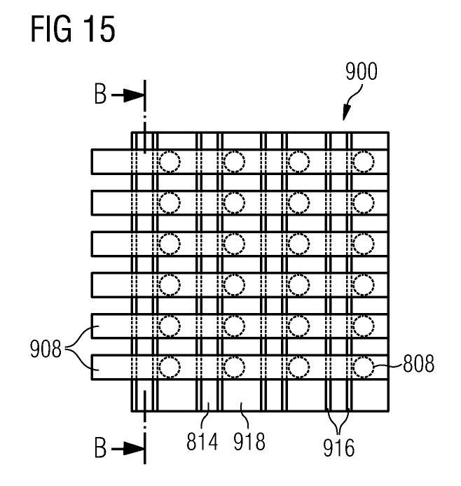

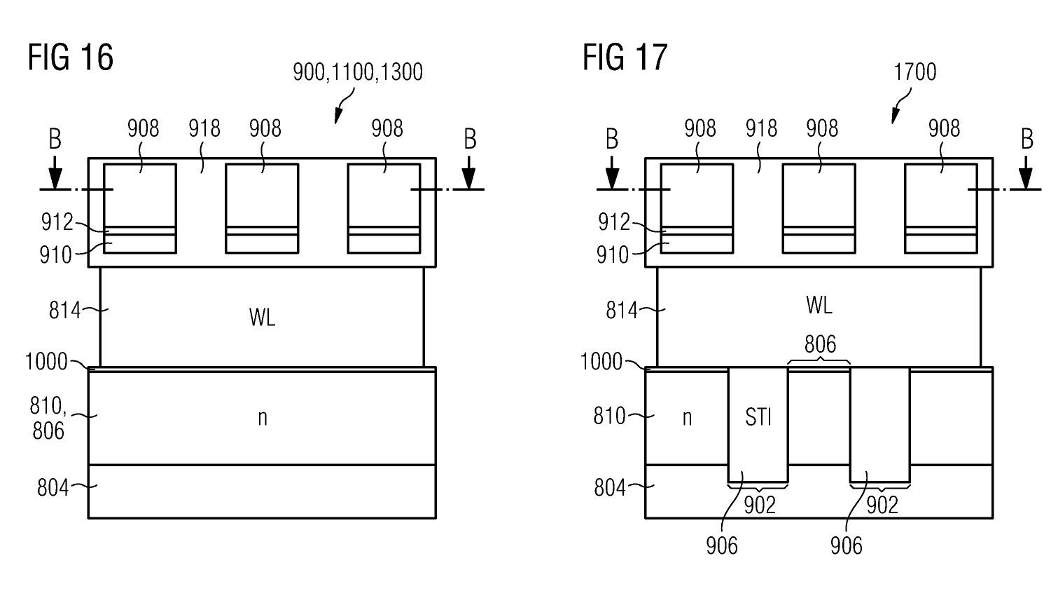

FIG. 16 shows the integrated circuits 900, 1100, 1300 along line B as indicated in FIG. 15. Isolation material 918 isolates the bit lines 908 against each other.

FIG. 17 shows an integrated circuit 1700 along line B as indicated in FIG. 15. In contrast to the integrated circuits 900, 1100, 1300, the isolation structure 902 completely laterally surrounds the select devices 806, i.e., the first semiconductor areas 810 and the second semiconductor areas 812. In contrast, integrated circuits 900, 1100, 1300 show the case where the isolation structure 902 has a stripe-like shape only extending along a direction parallel to line B which means that the select devices 806 are laterally not completely surrounded.

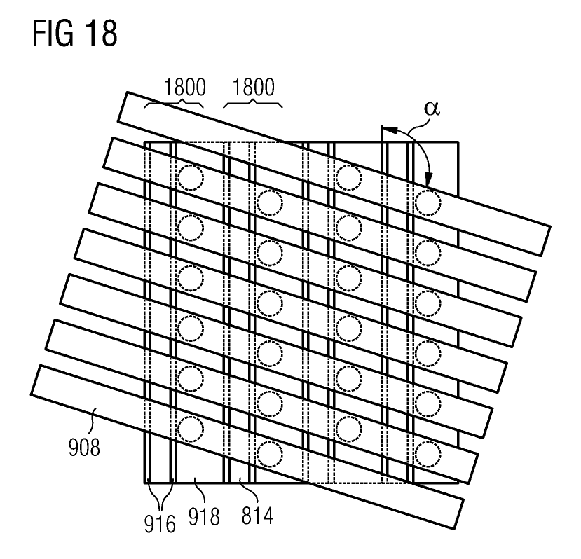

FIG. 18 shows a different embodiment. In this architecture, the word lines 814 and the bit lines 908 are not arranged perpendicular with respect to each other, but are oriented by an angle a with respect to each other, a being different from 90°. Further, the vertical positions of the select devices 806 differ from each other select device column 1800 by select device column 1800. Here, the vertical positions of the select devices 806 of every second select device column 1800 are the same. This results in a different litho layout for island levels such as the active silicon area or the contact level patterning conductive connection elements 808.

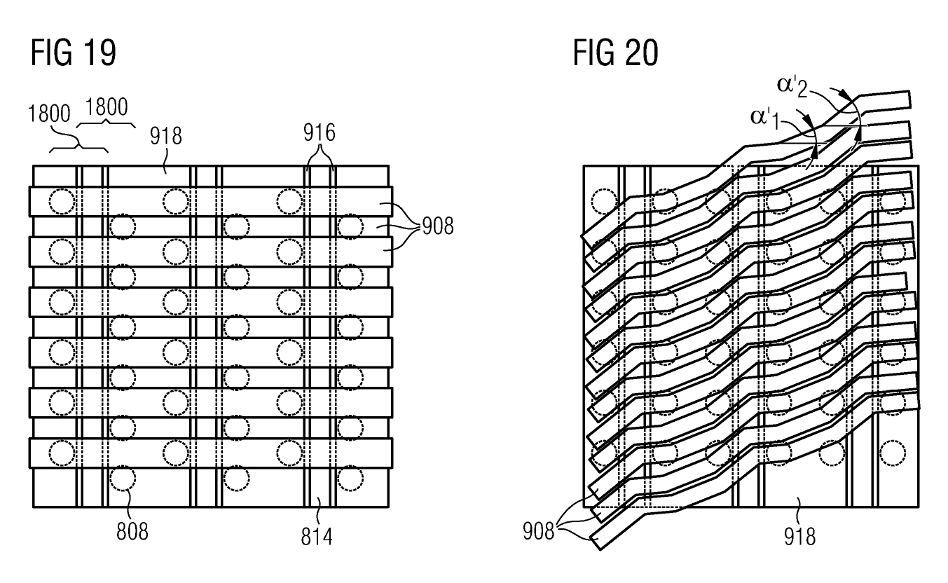

FIG. 19 shows an architecture (4F2 architecture) of word lines 814 and bit lines 908. In contrast architecture shown in FIG. 18 (6F2 architecture), the architecture shown in FIG. 19 shows the case where every word line 814 is connected to two neighboring columns 1800 of select devices 806. Every second bit line 908 is connected to the same columns 1800 of select devices 806. One effect of the architecture shown in FIG. 19 is that the memory density can be further increased. The bit lines are isolated against each other either by spacers (same heights) or by guiding them in different heights.

The architecture shown in FIG. 19 is chosen such that two neighboring select device columns 1800 have different vertical positions. In contrast, the architecture shown in FIG. 20 shows the case where the vertical positions of select devices 806 of neighboring select device columns 1800 are the same. However, the bit lines 908 are not oriented perpendicular to the word lines 814, as shown in the architecture of FIG. 19. Rather, the bit lines 908 show a plurality of different angles α′ against the word lines 814. One effect of this embodiment is that the distance between neighboring bit lines 908 can be increased which facilitates the manufacturing process of the integrated circuit.

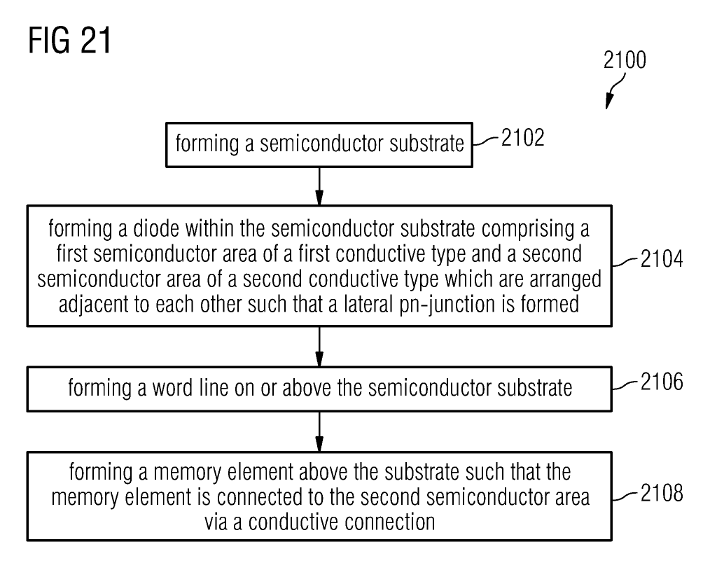

FIG. 21 shows a method 2100 of manufacturing an integrated circuit according to one embodiment of the present invention. At 2102, a semiconductor substrate is formed. At 2104, a diode is formed within the semiconductor substrate including a first semiconductor area of a first conductive type and a second semiconductor area of a second conductive type, which are arranged adjacent to each other such that a lateral pn-junction is formed. At 2106, a word line is formed on or above the semiconductor substrate. At 2108, a memory element is formed above the substrate such that the memory element is connected to the second semiconductor area via a conductive connection.

According to one embodiment of the present invention, the first semiconductor area and the second semiconductor area are formed such that they extend from the top surface of the semiconductor substrate into the semiconductor substrate.

According to one embodiment of the present invention, the formation of the first semiconductor area and of the second semiconductor area respectively includes: forming an isolation layer on the semiconductor substrate; forming a trench within the isolation layer; and introducing doping material into the semiconductor substrate by introducing the doping material into the trench. One effect of this embodiment is that no epitaxy process is needed in order to form the first semiconductor area and the second semiconductor area.

According to one embodiment of the present invention, after having introduced doping material into the semiconductor substrate, the trench is filled with conductive material.

According to one embodiment of the present invention, the side walls of the trench are covered with a side wall spacer before filling the conductive material into the trench.

According to one embodiment of the present invention, the conductive material is metal.

According to one embodiment of the present invention, the conductive material within the trench formed over the first semiconductor area forms the bit line.

According to one embodiment of the present invention, an isolation structure is formed within the semiconductor substrate which laterally isolates different memory cells at least partly against each other by an isolation structure.

According to one embodiment of the present invention, the isolation structure is formed by forming a trench structure within the semiconductor substrate, and by filling the trench structure with isolation material.

According to one embodiment of the present invention, the first semiconductor area and the second semiconductor area are formed such that they have the same depth.

According to one embodiment of the present invention, the first semiconductor area and the second semiconductor area are formed such that they have different depths, wherein the first semiconductor area is at least partly surrounded by the second semiconductor area, or vice versa.

According to one embodiment of the present invention, the formation of the first semiconductor area and of the second semiconductor area includes: forming a first semiconductor area within the semiconductor substrate, and forming the second semiconductor area within the first semiconductor area by introducing doping material of the second conductive type into a part of the first semiconductor area.

According to one embodiment of the present invention, a word line is formed on the first semiconductor area before introducing the doping material into the first semiconductor area, wherein the doping material is introduced into the part of the first semiconductor area which is not covered by the word line.

According to one embodiment of the present invention, the word lines and the bit lines are oriented rectangular with respect to each other. The memory elements form an array of memory element rows and memory element columns. The memory elements of two neighboring memory element columns have the same vertical positions. The memory elements belonging to different memory element columns and having the same vertical positions are connected to the same bit line.

According to one embodiment of the present invention, the word lines and the bit lines are oriented with respect to each other by an angle being different from 90°. The memory elements form an array of memory element rows and memory element columns. The memory elements of two neighboring memory element columns have different vertical positions. Memory elements belonging to different memory element columns and having different vertical positions are connected to the same bit line.

According to one embodiment of the present invention, the word lines and the bit lines are oriented rectangular with respect to each other. The memory elements form an array of memory element rows and memory element columns. The memory elements of every second neighboring memory element column have the same vertical positions. Memory elements belonging to every second memory element column and having the same vertical positions are connected to the same bit line.

According to one embodiment of the present invention, the word lines and the bit lines are oriented with respect to each other by angles being different from 90°. The memory elements form an array of memory element rows and memory element columns. The memory elements of two neighboring memory element columns have the same vertical positions. Memory elements belonging to every second memory element column and having different vertical positions are connected to the same bit line.

According to one embodiment of the present invention, the word lines and the bit lines are oriented with respect to each other by angles being different from 90°. The memory elements form an array of memory element rows and memory element columns. The memory elements of two neighboring memory element columns have the same vertical positions. The memory elements belonging to every second memory element column and having different vertical positions are connected to the same bit line.

In the following description, a method of manufacturing a memory cell of the integrated circuit 900 as shown in FIG. 10 will be described.

First, the semiconductor substrate 804 is provided. Then, the trench structure 904 is formed within the semiconductor substrate 804, e.g., by using a lithographic process. The trench structure 904 is filled with isolation material 906. A CMP (chemical mechanical polishing) process may, for example, be carried out in order to remove excessive isolation material 906. Then, an isolation layer is deposited on the semiconductor substrate 804. A first trench (word line trench) is formed within the isolation layer using, for example, a lithographic process. The trench extends through the isolation layer down to the top surface of the semiconductor substrate 804. Then, n-type doping material is introduced into the first trench. Thus, the n-type doping material is introduced into the semiconductor substrate 804, thereby forming the first semiconductor area 810. Then, a side wall spacer is formed within the first trench. After this, the first trench is filled with filling material which can be easily removed out of the first trench later on. The material may, for example, be photoresist material or NFC (near frictionless carbon) material. A recess process may be carried out in order to recess the material back into the first trench. Then, a contact hole (also referred to as second trench) is formed within the isolation layer adjacent to the first trench using, for example, a lithographic process. The second trench extends through the isolation layer down to the top surface of the semiconductor substrate 804. P-type doping material is introduced into the second trench. Thus, the p-type doping material is introduced into the semiconductor substrate 804, thereby forming the second semiconductor area 812. Then, the filling material is removed out of the first trench. Then, a metal is filled into the first trench and the second trench which comprises, e.g., Ti, Co, TiN, W, or a combination of these materials. A silicidation process is carried out by annealing the semiconductor substrate 804. Then, a metallic material (or a non metallic conductive material) is filled into the first trench and the second trench, e.g., in a single process. A CMP process may be carried out in order to remove excessive metallic material from the top surface of the isolation layer. The metallic material filled into the first trench forms the word line 814, and the metallic material filled into the second trench forms the conductive connection 808. After this, elements/layers above the first trench/second trench are formed using standard processes.

In the following description, a method of manufacturing a memory cell of the integrated circuit 1300 as shown in FIG. 14 will be described.

First, the semiconductor substrate 804 is provided. Then, an n-type well (extending over the whole memory cell array) is formed within the semiconductor substrate 804 extending from the top surface of the semiconductor substrate 804 into the semiconductor substrate 804. The formation of the n-type well may, for example, be carried out using an implantation process. Then, the trench structure 904 is formed, e.g., by using a lithographic process. The trench structure 904 is filled with isolation material 906. A CMP (chemical mechanical polishing) process may, for example, be carried out in order to remove excessive isolation material 906. Then, a first metal layer is formed on the semiconductor substrate 804. The metal layer may, for example, comprise Ti, Co, TiN, W, or a combination of these materials. After this, a second metal layer is formed on the metal layer. Then, the first metal layer and the second metal layer are patterned down to the top surface of the semiconductor substrate 804 such that the word line 814 is formed. After this, at least the side walls of the word line 814 are covered with word line side wall spacers 916. An isolation material (e.g., dielectric material) is deposited, followed by a CMP process. Then, a contact hole is formed within the isolation material adjacent to the word line 814 using, for example, a lithographic process. In order to form the contact hole, an etching process may be carried out which selectively etches the isolation material against the material of the side wall spacers (self alignment). The contact hole extends through the isolation material down to the top surface of the semiconductor substrate 804. P-type doping material is introduced into the contact hole. Thus, the p-type doping material is introduced into the semiconductor substrate 804 in order to form the second semiconductor area 812. The remaining part of the n-type well forms the first semiconductor area 810. The p-type doping material is introduced into the n-type well such that it is surrounded by the n-type well, i.e., the depth of the second semiconductor area 812 is not as large as the depth of the n-type well (i.e., the depth of the second semiconductor area). Then, a metal is introduced into the contact hole which comprises, e.g., Ti, Co, TiN, W, or a combination of these materials. A silicidation process is carried out by annealing the semiconductor substrate 804. Then, a metallic material (or a non metallic conductive material) is filled into the contact hole. A CMP process may be carried out in order to remove excessive conductive material from the top surface of the isolation material. The metallic material filled into the contact hole forms the conductive connection 808. After this, elements (e.g., memory elements)/layers are formed above the structure thus obtained using standard processes.

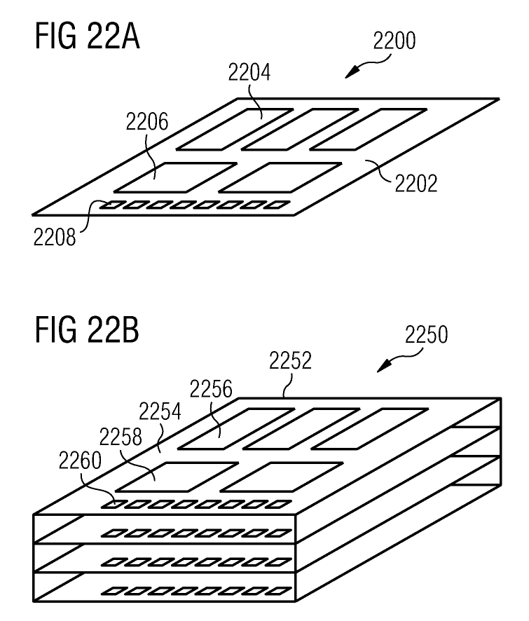

As shown in FIGS. 22A and 22B, in some embodiments, memory devices such as those described herein may be used in modules. In FIG. 22A, a memory module 2200 is shown, on which one or more integrated circuits 2204 are arranged on a substrate 2202. The integrated circuits 2204 may include numerous memory cells in accordance with an embodiment of the invention. The memory module 2200 may also include one or more electronic devices 2206, which may include memory, processing circuitry, control circuitry, addressing circuitry, bus interconnection circuitry, or other circuitry or electronic devices that may be combined on a module with a memory device, such as the integrated circuits 2204. Additionally, the memory module 2200 includes multiple electrical connections 2208, which may be used to connect the memory module 2200 to other electronic components, including other modules.

As shown in FIG. 22B, in some embodiments, these modules may be stackable, to form a stack 2250. For example, a stackable memory module 2252 may contain one or more integrated circuits 2256, arranged on a stackable substrate 2254. The integrated circuits 2256 contain memory cells in accordance with an embodiment of the invention. The stackable memory module 2252 may also include one or more electronic devices 2258, which may include memory, processing circuitry, control circuitry, addressing circuitry, bus interconnection circuitry, or other circuitry or electronic devices that may be combined on a module with a memory device, such as the integrated circuits 2256. Electrical connections 2260 are used to connect the stackable memory module 2252 with other modules in the stack 2250, or with other electronic devices. Other modules in the stack 2250 may include additional stackable memory modules, similar to the stackable memory module 2252 described above, or other types of stackable modules, such as stackable processing modules, control modules, communication modules, or other modules containing electronic components.

In the following description, further aspects of exemplary embodiments of the present invention will be explained.

Single-crystalline diodes have been shown which allow extremely high current densities and therefore very small cell sizes. According to one embodiment of the present invention, a 4-6F2 cell size lateral diode isolated PCM array is provided avoiding the use of selective Si epitaxy processes needed for conventional manufacturing processes. The present invention may also apply to other resistance changing memories like unipolar resistive memories such as transision metal oxide or perovskite memories.

Conventional integrated diode selected PCRAM arrays are based on selective Si epitaxy processes in an oxide via with an implanted n+ wordline. This implanted wordline has the drawback of a very high parasitic resistance, requiring stiching contacts at least every 8 bits. This increases the effective cell size. In addition, the requirements for the selective epitaxy are quite severe, with only a narrow operating window trading growth time, temperature budget, and defect density/diode quality.

According to one embodiment of the present invention, a diode based PCRAM architecture and integration flow is provided. This diode architecture enables very compact memory arrays down to 4F²-6F² cell size. Critical process steps like selective Si epitaxy are avoided, while parasitic series resistance is minimized by metal word lines and large contact areas.

Effects of embodiments of the present invention are: Cell size is 4-6F², F being the smallest feature size; Planar diode architecture with metal word line (WL) is possible; Large area low resistance WL contacts are possible; Diode fabrication based on ion implantation is possible; No critical epi-Si processes are required.

According to one embodiment of the present invention, a diode array architecture is disclosed with a metal wordline and an implanted laterally connected pn diode, allowing a straightforward integration flow.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising a plurality of resistance changing memory cells, the integrated circuit comprising:
a semiconductor substrate;
a select device arranged within the semiconductor substrate, wherein the select device comprises a diode comprising a first semiconductor area of a first conductive type and a second semiconductor area of a second conductive type, the first and second semiconductor areas being arranged adjacent to each other such that a lateral pn-junction area is formed;
a resistance changing memory element arranged above the semiconductor substrate;
a word line arranged on or above the semiconductor substrate, the first semiconductor area being coupled to the word line; and
a conductive connection element, the second semiconductor area being coupled to the memory element via the conductive connection element.

2. The integrated circuit according to claim 1, wherein the first semiconductor area and the second semiconductor area extend from a top surface of the semiconductor substrate into the semiconductor substrate.

3. The integrated circuit according to claim 1, wherein the word line directly contacts the first semiconductor area.

4. The integrated circuit according to claim 1, further comprising an isolation layer covering the semiconductor substrate, a first trench and a second trench being disposed in the isolation layer, wherein the word line is formed by conductive material within the first trench, and wherein conductive connection element is formed by conductive material within the second trench.

5. The integrated circuit according to claim 4, wherein the word line comprises metal.

6. The integrated circuit according to claim 5, wherein the conductive connection comprises metal.

7. The integrated circuit according to claim 4, wherein side walls of the first trench are covered with a side wall spacer.

8. The integrated circuit according to claim 1, wherein the select device comprises one of a plurality of select devices arranged within the semiconductor substrate, the select devices forming a select device array having select device columns and select device rows, wherein neighboring select device columns are laterally isolated against each other by a trench filled with isolation material.

9. The integrated circuit according to claim 8, wherein each select device is laterally completely enclosed by a trench filled with isolation material.

10. The integrated circuit according to claim 1, wherein the first semiconductor area and the second semiconductor area have substantially the same depth.

11. The integrated circuit according to claim 1, wherein the word line has a height that is smaller than a height of the conductive connection element.

12. The integrated circuit according to claim 1, wherein, between the first semiconductor area and the second semiconductor area, only a lateral pn-junction is formed.

13. The integrated circuit according to claim 1, wherein the first semiconductor area and the second semiconductor area have different depths and wherein the first semiconductor area is at least partly surrounded by the second semiconductor area, or vice versa.

14. The integrated circuit according to claim 1, wherein the memory element is a phase change memory element.

15. The integrated circuit according to claim 1, further comprising a plurality of memory elements, a plurality of word lines and a plurality of bit lines, the memory element being one of the plurality of memory elements and the word line being one of the plurality of word lines, wherein the word lines and the bit lines are arranged rectangular with respect to each other,
wherein the memory elements form an array of memory element rows and memory element columns,
wherein the memory elements of two neighboring memory element columns have the same vertical positions, and
wherein memory elements belonging to different memory element columns and having the same vertical positions are connected to the same bit line.

16. The integrated circuit according to claim 1, further comprising a plurality of memory elements, a plurality of word lines and a plurality of bit lines, the memory element being one of the plurality of memory elements and the word line being one of the plurality of word lines,
wherein the word lines and the bit lines are oriented with respect to each other by an angle being different from 90°,
wherein the memory elements form an array of memory element rows and memory element columns,
wherein the memory elements of two neighboring memory element columns have different vertical positions, and
wherein memory elements belonging to different memory element columns and having different vertical positions are connected to the same bit line.

17. The integrated circuit according to claim 1, further comprising a plurality of memory elements, a plurality of word lines and a plurality of bit lines, the memory element being one of the plurality of memory elements and the word line being one of the plurality of word lines,
wherein the word lines and the bit lines are oriented rectangular with respect to each other,
wherein the memory elements form an array of memory element rows and memory element columns,
wherein the memory elements of every second neighboring memory element column have the same vertical positions,
wherein memory elements belonging to every second memory element column and having the same vertical positions are connected to the same bit line.

18. The integrated circuit according to claim 1, further comprising a plurality of memory elements, a plurality of word lines and a plurality of bit lines, the memory element being one of the plurality of memory elements and the word line being one of the plurality of word lines,
wherein the word lines and the bit lines are oriented with respect to each other by angles being different from 90°,
wherein the memory elements form an array of memory element rows and memory element columns,
wherein the memory elements of two neighboring memory element columns have the same vertical positions,
wherein memory elements belonging to every second memory element column and having different vertical positions are connected to the same bit line.

19. The integrated circuit according to claim 1, further comprising a plurality of memory elements, a plurality of word lines and a plurality of bit lines, the memory element being one of the plurality of memory elements and the word line being one of the plurality of word lines,
wherein the word lines and the bit lines are oriented with respect to each other by angles being different from 90°,
wherein the memory elements form an array of memory element rows and memory element columns,
wherein the memory elements of two neighboring memory element columns have the same vertical positions,
wherein memory elements belonging to every second memory element column and having different vertical positions are connected to the same bit line.

20. An integrated circuit comprising a plurality of resistance changing memory cells, each memory cell comprising:
a semiconductor substrate,
a select device arranged within the semiconductor substrate,
a resistance changing memory element being arranged above the semiconductor substrate,
wherein the select device is a diode comprising a first semiconductor area of a first conductive type and a second semiconductor area of a second conductive type which are arranged adjacent to each other, wherein the first semiconductor area and the second semiconductor area are formed such that they extend from the top surface of the semiconductor substrate into the semiconductor substrate,
wherein the first semiconductor area is connected to a metallic word line arranged on the first semiconductor area,
wherein the second semiconductor area is connected to the memory element via a conductive connection element.

21. A method of manufacturing an integrated circuit comprising a plurality of resistance changing memory cells, the method comprising:
forming a semiconductor substrate,
forming a diode within the semiconductor substrate, the diode comprising a first semiconductor area of a first conductive type and a second semiconductor area of a second conductive type which are arranged adjacent to each other such that a pn-junction is formed between the first semiconductor area and the second semiconductor area which comprises a lateral pn-junction area,
forming a word line on or above the semiconductor substrate,
forming a memory element above the substrate such that the memory element is connected to the second semiconductor area via a conductive connection.

22. The method according to claim 21, wherein the first semiconductor area and the second semiconductor area are formed such that they extend from the top surface of the semiconductor substrate into the semiconductor substrate.

23. The method according to claim 21, wherein the formation of the first semiconductor area and of the second semiconductor area respectively comprises:
forming an isolation layer on the semiconductor substrate;
forming a trench within the isolation layer; and
introducing doping material into the semiconductor substrate by introducing the doping material into the trench.

24. The method according to claim 23, further comprising, after introducing doping material into the semiconductor substrate, filling the trench with conductive material.

25. The method according to claim 24, further comprising covering side walls of the trench with a side wall spacer before filling the trench with conductive material.
